(19) United States
(12) Patent Application Publication
(10) Pub. No.: US 2025/0266612 A1
(43) Pub. Date: Aug. 21, 2025

(54) ANTENNA MODULE AND ELECTRONIC DEVICE

(71) Applicant: Universal Global Technology (Kunshan) Co., Ltd., Jiangsu Province (CN)

(72) Inventors: YU SHENG SU, Jiangsu Province (CN); CHIEN-HUNG CHOU, Jiangsu Province (CN); JUI CHIH CHIEN, Jiangsu Province (CN); MENG-LIEN CHEN, Jiangsu Province (CN)

(21) Appl. No.: 19/021,212

(22) Filed: Jan. 15, 2025

(30) Foreign Application Priority Data
Feb. 21, 2024 (CN) 202410192932.4

(51) Int. Cl. H01Q 1/24; G01R 29/08; H01Q 9/04; H01Q 9/42

(52) U.S. Cl. CPC H01Q 1/243; G01R 29/0814; G01R 29/0878; H01Q 9/0485; H01Q 9/42

(57) ABSTRACT

An antenna module includes an antenna unit and a sensing unit. The antenna unit is made of a metal material. The antenna unit includes a signal portion and a ground portion, and the signal portion includes a first signal section. The sensing unit is made of a metal material and electrically connected to a sensor. The sensing unit includes a first sensing section and a second sensing section. The first sensing section and the second sensing section are electrically connected. A normal direction of the first sensing section is not parallel to a normal direction of the second sensing section. The sensing unit is not connected to the antenna unit. The first sensing section is located adjacent to the first signal section. The normal direction of the second sensing section is not parallel to a normal direction of the first signal section.

### RELATED APPLICATIONS

This application claims priority to China Application Serial Number 202410192932.4, filed Feb. 21, 2024, which is herein incorporated by reference.

### BACKGROUND

### Technical Field

The present disclosure relates to an antenna module and an electronic device. More particularly, the present disclosure relates to an antenna module and an electronic device including a sensing unit.

### Description of Related Art

Driven by human beings' pursuit of convenient life, various wireless communication systems and their radio frequency technologies have been developed. For example, with the rise of 5G (5th generation mobile network) and WiFi 6E in recent years, the increasing number of antennas in electronic devices makes designs of antenna modules more difficult. For example, it will be more difficult for an electronic device to pass the regulatory test of SAR (specific absorption rate) when it has multiple antennas.

Therefore, how to make the radio frequency characteristics of antenna modules in electronic devices meet specification requirements while effectively reducing production costs has become an important issue in today's market.

### SUMMARY

According to one aspect of the present disclosure, an antenna module includes an antenna unit and a sensing unit. The antenna unit is made of a metal material. The antenna unit includes a signal portion and a ground portion, and the signal portion includes a first signal section. The sensing unit is made of a metal material and electrically connected to a sensor. The sensing unit includes a first sensing section and a second sensing section. The first sensing section and the second sensing section are electrically connected. A normal direction of the first sensing section is not parallel to a normal direction of the second sensing section. The sensing unit is not connected to the antenna unit. The first sensing section is located adjacent to the first signal section. The normal direction of the second sensing section is not parallel to a normal direction of the first signal section.

According to another aspect of the present disclosure, an electronic device includes the antenna module of the aforementioned aspect. The sensing unit further includes a third sensing section, the first sensing section, the second sensing section and the third sensing section are electrically connected in sequence, and a second included angle formed by an extending direction of the second sensing section and an extending direction of the third sensing section is between 60 degrees and 120 degrees. The first sensing section and the third sensing section are respectively adjacent to two opposite surfaces of the electronic device.

### BRIEF DESCRIPTION OF THE DRAWINGS

The present disclosure can be more fully understood by reading the following detailed description of the embodiment, with reference made to the accompanying drawings as follows:

FIG. 1 is a three-dimensional view of an antenna module according to the first embodiment of the present disclosure.

FIG. 2 is a three-dimensional view of an antenna unit and a sensing unit of the antenna module in FIG. 1.

FIG. 3 is another three-dimensional view of the antenna unit and the sensing unit of the antenna module in FIG. 1.

FIG. 4 is a side view of the antenna unit and the sensing unit of the antenna module in FIG. 1.

FIG. 5 is a front view of the antenna unit and the sensing unit of the antenna module in FIG. 1.

FIG. 6 is a schematic view of S11 parameters of the antenna module in FIG. 1 and an antenna module without a sensing unit.

FIG. 7 is a schematic view of an electronic device according to the second embodiment of the present disclosure.

### DETAILED DESCRIPTION

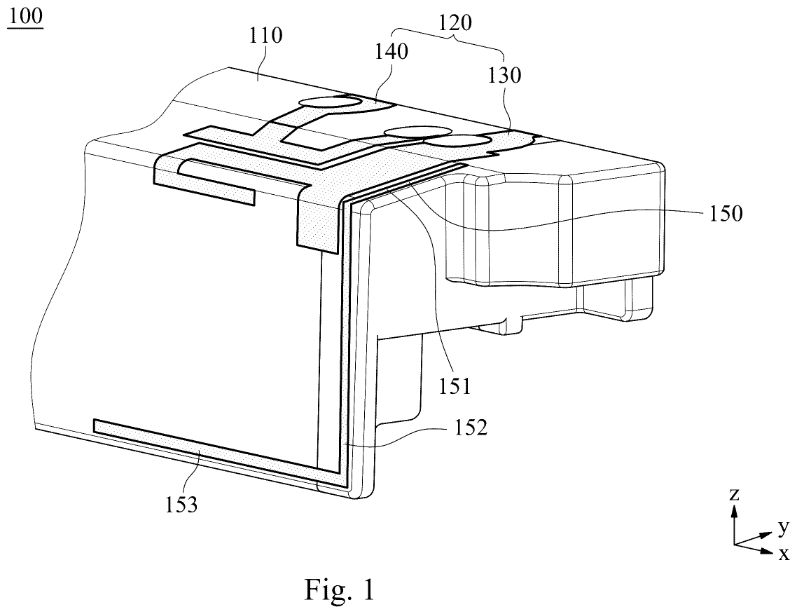

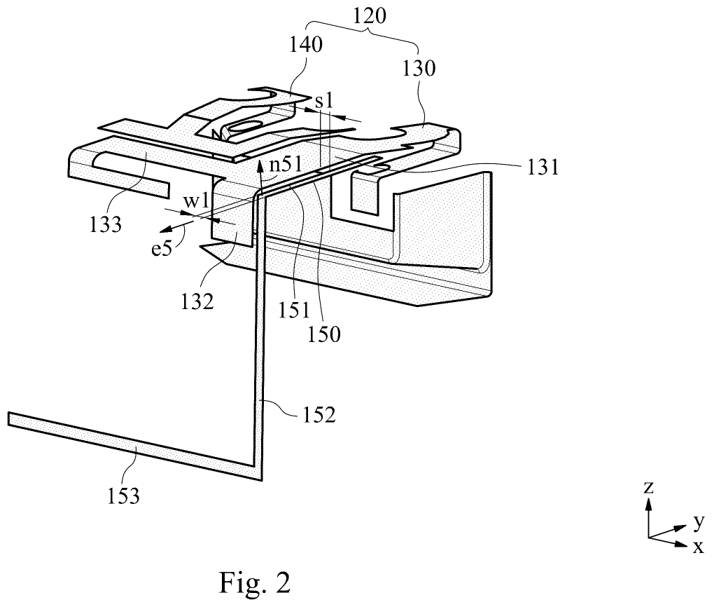

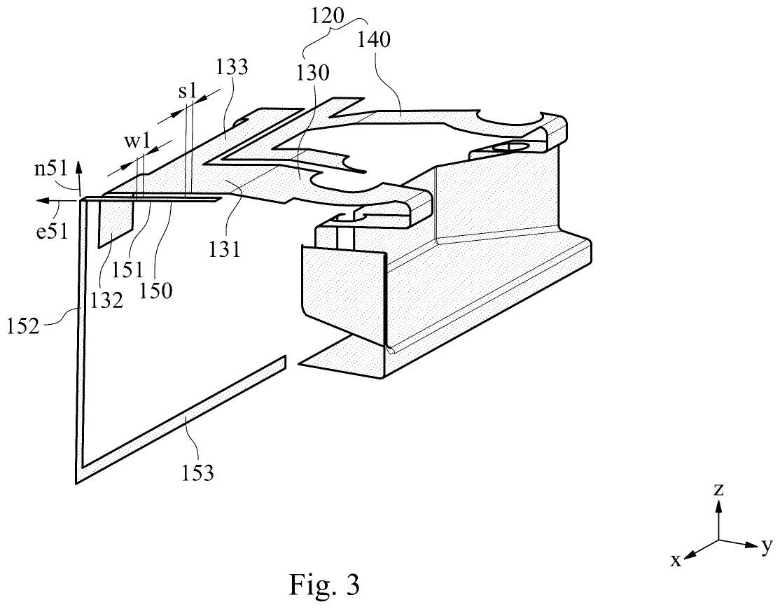

FIG. 1 is a three-dimensional view of an antenna module 100 according to the first embodiment of the present disclosure. FIG. 2 is a three-dimensional view of an antenna unit 120 and a sensing unit 150 of the antenna module 100 in FIG. 1. FIG. 3 is another three-dimensional view of the antenna unit 120 and the sensing unit 150 of the antenna module 100 in FIG. 1. The drawings of the present disclosure are drawn based on a rectangular coordinate system in which a first direction x, a second direction y and a third direction z are perpendicular to each other. With reference to FIG. 1 to FIG. 3, the antenna module 100 includes the antenna unit 120 and the sensing unit 150, and the antenna module 100 can also be called a sensing module. The antenna unit 120 is made of a metal material. The antenna unit 120 includes a signal portion 130 and a ground portion 140, and the signal portion 130 includes a first signal section 131. The sensing unit 150 is made of a metal material and electrically connected to a sensor (not shown in drawings). The sensing unit 150 includes a first sensing section 151 and a second sensing section 152. The first sensing section 151 and the second sensing section 152 are electrically connected. A normal direction n51 of the first sensing section 151 is not parallel to a normal direction of the second sensing section 152. Specifically, one end of the first signal section 131 facing the positive direction of the second direction y is directly or indirectly electrically connected to a feeding port, and one end of the first sensing section 151 facing the positive direction of the second direction y is electrically connected to the sensor. Furthermore, the first sensing section 151, the second sensing section 152 and the third sensing section 153 of the present disclosure serve as electrodes of the sensing unit 150 facing different directions. The normal direction of each of the first sensing section 151, the second sensing section 152 and the third sensing section 153 is the direction that the electrode faces, and only the normal direction n51 of the first sensing section 151 is drawn for the sake of clearly drawing.

The sensing unit 150 is not connected to the antenna unit 120. The first sensing section 151 is located adjacent to the first signal section 131. The normal direction of the second sensing section 152 is not parallel to a normal direction of the first signal section 131. Therefore, it helps to achieve multi-directional sensing effects by the sensing unit 150 without affecting the antenna characteristics of the antenna unit 120.

In detail, the antenna module 100 may further include a dielectric unit 110, which is specifically made of a plastic dielectric material. The antenna unit 120 and the sensing unit 150 are specifically in form of metal sheet and extended along a surface of the dielectric unit 110. The antenna unit 120 and the sensing unit 150 are made by a LDS (laser direct structuring) method. Furthermore, the sensor may be a proximity sensor. Moreover, the sensor may be a SAR (specific absorption rate) sensor. Therefore, the SAR sensor is inductively driven by the metal sheet of the sensing unit 150 designed around the antenna unit 120, thereby achieving the effect of reducing the device power after the head or/and hand touch or approach the antenna module 100.

The signal portion 130 may be not connected to and may be coupled to the ground portion 140. The first sensing section 151, the first signal section 131 and the ground portion 140 are arranged in sequence along the first direction x. Therefore, taking a monopole coupling antenna as an example, the antenna module 100 is coupled to the ground metal via the antenna feeding path, and a coupling line (i.e., the sensing unit 150) is added around it to improve the antenna characteristics and serve as a SAR sensor. Furthermore, the term “connect” described in the present disclosure refers to the direct or indirect physical connection between two components, and the term “couple” described herein refers to two components separated from each other and has no physical connection, but the electric field energy generated by the current of one component excites the electric field energy of the other component.

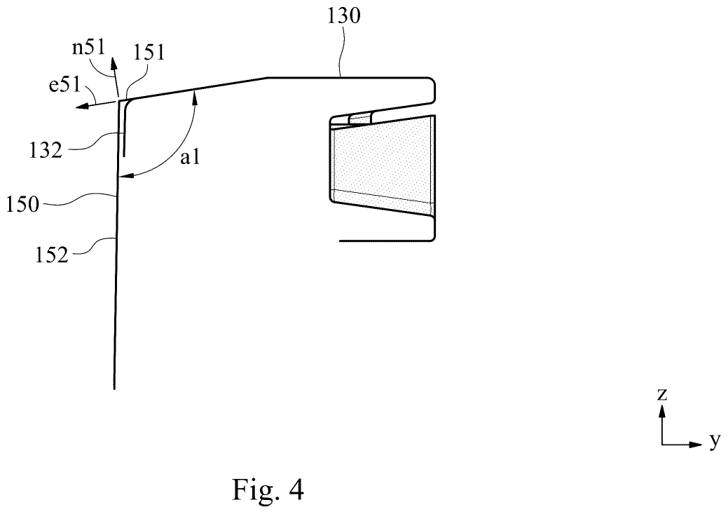

FIG. 4 is a side view of the antenna unit 120 and the sensing unit 150 of the antenna module 100 in FIG. 1. With reference to FIG. 4, a first included angle a1 formed by an extending direction e51 of the first sensing section 151 and an extending direction of the second sensing section 152 may be between 60 degrees and 120 degrees. Therefore, the first sensing section 151 and the second sensing section 152 can be used for respectively providing the sensing results in different planes or directions. Furthermore, the first included angle a1 may be between 75 degrees and 105 degrees. In the first embodiment, the first included angle a1 is 100 degrees.

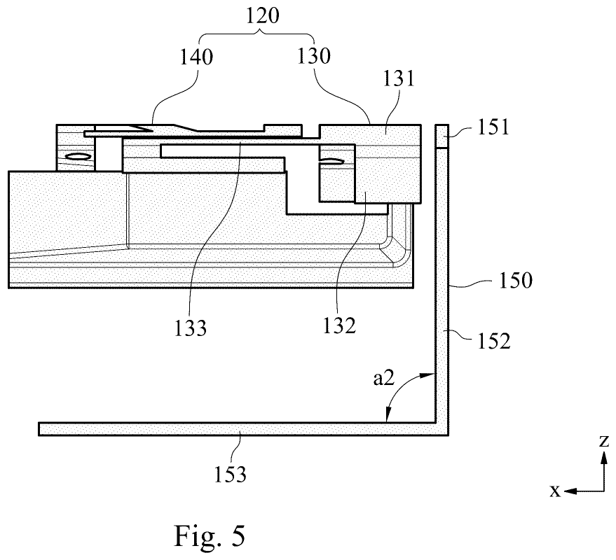

FIG. 5 is a front view of the antenna unit 120 and the sensing unit 150 of the antenna module 100 in FIG. 1. With reference to FIG. 1 and FIG. 5, the sensing unit 150 may further include a third sensing section 153. The first sensing section 151, the second sensing section 152 and the third sensing section 153 are electrically connected in sequence. A second included angle a2 formed by the extending direction of the second sensing section 152 and an extending direction of the third sensing section 153 may be between 60 degrees and 120 degrees. Therefore, the second sensing section 152 and the third sensing section 153 can be used for respectively providing the sensing results in different planes or directions. Moreover, the first sensing section 151 and the third sensing section 153 of the antenna module 100 are beneficial to achieve well sensing effects in two opposite planes or two directions (that is, the two directions are about 180 degrees apart). Furthermore, the second included angle a2 may be between 75 degrees and 105 degrees. In the first embodiment, the second included angle a2 is 90 degrees.

A normal direction of the second sensing section 152 may be parallel to a normal direction of the third sensing section 153. Therefore, it is advantageous in reducing production complexity. Specifically, the normal direction of the second sensing section 152 and the normal direction of the third sensing section 153 are both parallel to the second direction y.

With reference to FIG. 1 to FIG. 4, the signal portion 130 may further include a second signal section 132. The first signal section 131 and the second signal section 132 are electrically connected. The first sensing section 151 is adjacent, parallel and coupled to the first signal section 131, and the second sensing section 152 is adjacent, parallel and coupled to the second signal section 132. Therefore, the antenna module 100 adopting a coupled structure design is beneficial to reduce design complexity.

The signal portion 130 may further include a third signal section 133. The first signal section 131 and the third signal section 133 are electrically connected. The normal direction of the first signal section 131 is parallel to a normal direction of the third signal section 133. An extension direction of the first signal section 131 is not parallel to an extension direction of the third signal section 133. Therefore, the first signal section 131 of the signal portion 130 extends to the third signal section 133 thereof and is coupled with the ground portion 140, so as to provide the communication operating frequency of the antenna module 100.

With reference to FIG. 3, a ratio of a spacing s1 between the first sensing section 151 and the first signal section 131 to a width w1 of the first sensing section 151 may be between 0.5 and 1.8. Therefore, it helps to achieve the sensing performance required by the antenna module 100 and effectively improve the antenna characteristics. Specifically, the overall appearance dimensions of the antenna module 100 are 17.4 mm (in the first direction x), 12.3 mm (in the second direction y) and 12.2 mm (in the third direction z), and the path of the sensing unit 150 is provided as a SAR sensor pad near the side of the signal portion 130. The total length of the sensing unit 150 is 33.1 mm. The spacing s1 between the first sensing section 151 and the first signal section 131 is 0.6 mm, the width w1 of the sensing unit 150 (the first sensing section 151) is 0.5 mm, and the ratio of the spacing s1 between the first sensing section 151 and the first signal section 131 to the width w1 of the first sensing section 151 is 1.2.

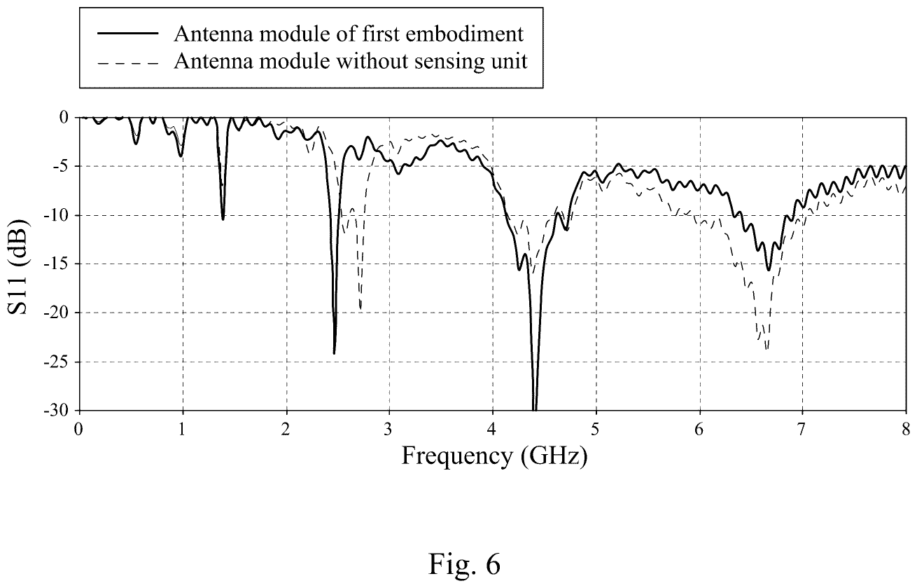

FIG. 6 is a schematic view of S11 parameters of the antenna module 100 in FIG. 1 and an antenna module without a sensing unit, and FIG. 6 specifically includes the S11 parameters of the antenna module 100 of the first embodiment and an antenna module that does not include a sensing unit (e.g., there is no sensing unit 150 designed around the antenna unit 120). As shown in FIG. 6, taking the reflection loss of 6 dB (i.e., the S11 parameter is −6 dB) as the reference standard, the bandwidth of the antenna module 100 at 2.4 GHz is approximately 144 MHz, and the bandwidth from 5 GHz to WiFi 6E is approximately 3400 MHz, thereby the antenna module 100 can be used for the frequency bands of WiFi 2.4 GHz, 5 GHz and 6E. Furthermore, through the cooperation design of the antenna unit 120 and the sensing unit 150, the S11 parameter of the antenna module 100 is improved by an average of 10 dB at the frequency band of 2.4 GHz to 2.48 GHz, so the antenna module 100 simultaneously achieves the advantages of the sensing function of the sensing unit 150 and improving antenna characteristics. It should be noted that the WiFi frequency band is only used as a design example for the antenna module 100. The LTE (Long Term Evolution) or 5G NR (New Radio) frequency band may be also used for the antenna module of the present disclosure, and the present disclosure is not limited thereto.

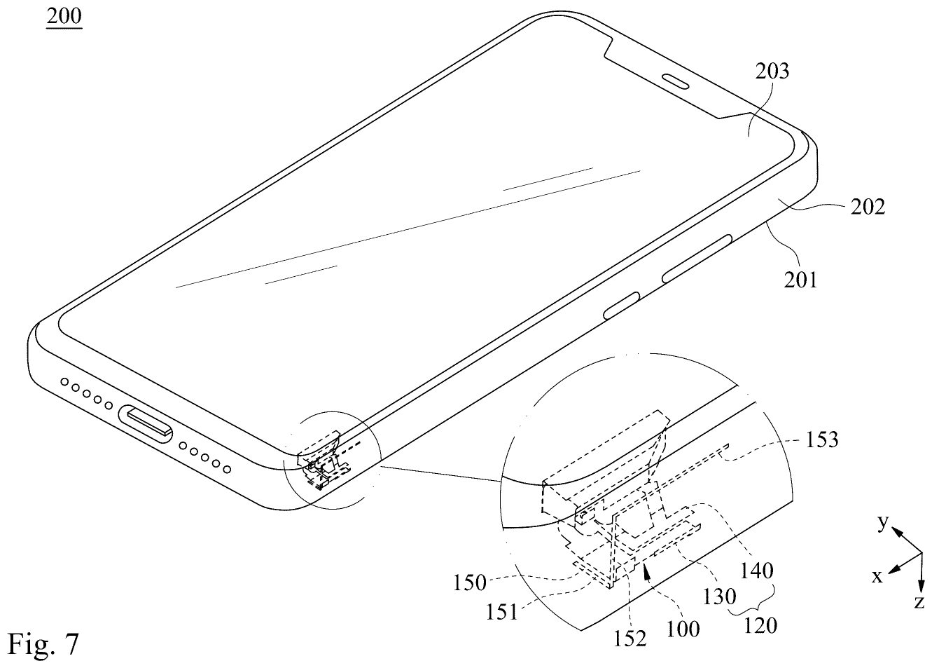

FIG. 7 is a schematic view of an electronic device 200 according to the second embodiment of the present disclosure. With reference to FIG. 7, the electronic device 200 includes the antenna module 100 of the aforementioned first embodiment. The electronic device 200 is specifically a smart phone, and the present disclosure is not limited thereto. The antenna module 100 includes the antenna unit 120 and the sensing unit 150. The first sensing section 151, the second sensing section 152 and the third sensing section 153 of the sensing unit 150 are electrically connected in sequence. The first included angle a1 formed by the extending direction e51 of the first sensing section 151 and the extending direction of the second sensing section 152 may be between 60 degrees and 120 degrees, and the second included angle a2 formed by the extending direction of the second sensing section 152 and the extending direction of the third sensing section 153 is between 60 degrees and 120 degrees. The first sensing section 151 and the third sensing section 153 are respectively adjacent to two opposite surfaces 201, 203 of the electronic device 200. For example, the surfaces 201, 203 are respectively the back cover surface and the screen surface of the electronic device 200, and the present disclosure is not limited thereto. Therefore, the sensing unit 150 of the antenna module 100 extends from the first sensing section 151 to the second sensing section 152 and the third sensing section 153 in sequence, that is, the sensing direction of the sensing unit 150 extends from the back cover side of the electronic device 200 to the screen side thereof, thus helping to achieve well sensing effects on the three surfaces 201, 202, 203 of the electronic device 200.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An antenna module, comprising:
an antenna unit made of a metal material, wherein the antenna unit comprises a signal portion and a ground portion, and the signal portion comprises a first signal section; and
a sensing unit made of a metal material and electrically connected to a sensor, wherein the sensing unit comprises a first sensing section and a second sensing section, the first sensing section and the second sensing section are electrically connected, and a normal direction of the first sensing section is not parallel to a normal direction of the second sensing section;
wherein the sensing unit is not connected to the antenna unit, the first sensing section is located adjacent to the first signal section, and the normal direction of the second sensing section is not parallel to a normal direction of the first signal section.

2. The antenna module of claim 1, further comprising:
a dielectric unit made of a dielectric material, wherein the antenna unit and the sensing unit are extended along a surface of the dielectric unit and made by a LDS (laser direct structuring) method;
wherein the sensor is a SAR (specific absorption rate) sensor.

3. The antenna module of claim 1, wherein the signal portion is not connected to and is coupled to the ground portion, and the first sensing section, the first signal section and the ground portion are arranged in sequence along a first direction.

4. The antenna module of claim 1, wherein a first included angle formed by an extending direction of the first sensing section and an extending direction of the second sensing section is between 60 degrees and 120 degrees.

5. The antenna module of claim 1, wherein the sensing unit further comprises a third sensing section, the first sensing section, the second sensing section and the third sensing section are electrically connected in sequence, and a second included angle formed by an extending direction of the second sensing section and an extending direction of the third sensing section is between 60 degrees and 120 degrees.

6. The antenna module of claim 5, wherein a normal direction of the second sensing section is parallel to a normal direction of the third sensing section.

7. The antenna module of claim 1, wherein the signal portion further comprises a second signal section, the first signal section and the second signal section are electrically connected, the first sensing section is parallel and coupled to the first signal section, and the second sensing section is adjacent, parallel and coupled to the second signal section.

8. The antenna module of claim 7, wherein a ratio of a spacing between the first sensing section and the first signal section to a width of the first sensing section is between 0.5 and 1.8.

9. The antenna module of claim 1, wherein the signal portion further comprises a third signal section, the first signal section and the third signal section are electrically connected, the normal direction of the first signal section is parallel to a normal direction of the third signal section, and an extension direction of the first signal section is not parallel to an extension direction of the third signal section.

10. An electronic device, comprising:
the antenna module of claim 5, wherein the first sensing section and the third sensing section are respectively adjacent to two opposite surfaces of the electronic device.
